(19) United States
(12) Patent Application Publication
(10) Pub. No.: US 2006/0054494 A1
(43) Pub. Date: Mar. 16, 2006

(54) Physical vapor deposition apparatus for depositing thin multilayer films and methods of depositing such films

(75) Inventor: Ira Reiss, New City, NY (US)

Correspondence Address: WOOD, HERRON & EVANS, LLP, 2700 CAREW TOWER, 441 VINE STREET, CINCINNATI, OH, 45202, US

(73) Assignee: Veeco Instruments Inc., Woodbury, NY (US)

(21) Appl. No.: 10/943,115

(22) Filed: Sep. 16, 2004

(51) Int. Cl. C23C 14/00; C23C 14/32

(52) U.S. Cl. 204/192.12; 204/298.02

(57) ABSTRACT

A compact and economical physical vapor deposition (PVD) module for depositing thin film multi-layers with extreme control of thickness, uniformity and surface smoothness. The module includes multiple deposition sources positioned in a conical cluster with confocal arrangement about a single common deposition zone that is defined by a deposition aperture and a substrate carrier with two independently controlled (rotation and scanning) substrate motions. A substrate carrier rotates the substrate at high speed and translates the substrate through the deposition zone. The module lacks a shutter for controlling the film deposition process. Methods of depositing thin film multi-layers are also described.

### FIELD OF THE INVENTION

The present invention relates to apparatus and methods for processing substrates like semiconductor wafers and data storage components and, more particularly, to improved apparatus and methods for depositing one or more layers or thin films of material on such substrates.

### BACKGROUND OF THE INVENTION

Most physical vapor deposition (PVD) modules and tools currently in use by the data storage, semiconductor and related industries deposit materials with the substrate stationary and depend on the use of oversize targets, in relation to the substrate size, or extremely long target-to-substrate distances, to achieve uniformity. Despite use of these uneconomical techniques, the resulting deposition uniformity is generally limited to 1% one standard deviation (i.e., sigma) of the deposited layer thickness. Feature size reductions in the data storage and semiconductor industries have resulted in requirements for thin films with sub-nanometer control of thickness and uniformity to less than 0.3 percent one standard deviation and surface smoothness to the sub-angstrom level. Some conventional PVD tools add substrate rotation in an attempt to improve azimuthal uniformity. However, rotating the substrate does not effect radial uniformity. Therefore, the ability of conventional PVD tools to achieve the necessary performance in data storage and semiconductor applications is becoming more difficult and increasingly expensive.

In particular, the manufacture of sensor elements for giant magnetoresistance (GMR) and tunneling magnetoresistance (TMR) read/write heads for the data storage industry and similar devices requires PVD depositions in a high vacuum environment of multiple materials with minimal latency time between the deposition of each individual layer in a deposited film stack of multiple materials. These measures are required to assure that the interfaces between the layers are precisely controlled and that the background residual gases inside the vacuum environment do not contaminate these interfaces. To achieve the required minimum latency time, multiple sputter sources are routinely located in a single vacuum chamber and the substrate is moved from one sputter source to the next sputter source and/or the sputter sources are sequentially activated.

One class of conventional PVD modules or tools used for depositing multiple layers may be broadly described as a “dial-index” configuration in which several round sputter sources equal to or greater than the required number of different materials in the film stack are located about the periphery of the top of a large cylindrical vacuum chamber. The substrate is placed in a fixture that constitutes part of an assembly with a rotary arm. The arm and fixture assembly are sized such that the center of the substrate is coincident with the center of the sputter source. The fixture and rotary arm assembly are sequentially indexed from one sputter source to the next until the requisite film stack is deposited.

The size of the sputter source required to achieve a satisfactory uniformity in the thickness of the deposited films is approximately 1.5 to 2.0 times the diameter of the substrate. The target of the sputter source and the confronting surface of the substrate are parallel and spaced approximately 2 to 9 inches apart. A rotary shutter located between the substrate and the sputter source is used to control the deposition on the substrate.

Two primary weaknesses are intrinsic to the dial-index configuration. One weakness is the need for a shutter to control the deposition and the effect of the shutter actuation time on the control of the thickness and uniformity of the film. As an alternative to shuttering, the use of plasma turn on/turn off to control film thickness would significantly affect the quality and smoothness of the deposited films. Another weakness in the design of dial-index PVD tools is the large size and consequent cost of the module or tool, which is driven by the cathode size of the sputter source required to provide satisfactory thickness uniformity for the given substrate size and the number of materials required in the film stack.

Another class of conventional PVD modules or tools clusters tilted sputter sources in a conical arrangement, which allows for a more compact chamber design than dial-index PVD tools and usually allows for dispensing with the index motion. However, this design creates several problems. Because the sputter sources are tilted and offset with respect to the substrate, high-speed substrate rotation must be added to the fixture to achieve azimuthal uniformity. To fit the required number of sputter sources requires the use of smaller sputter sources, approximately the same size as the substrate. This design also retains the use of, and the inherent disadvantage of, a shutter for controlling the deposition on the substrate. Control over the thickness of sub-nanometer films is difficult because of the shutter timing requirements. These tools and dial-index tools generally suffer from the disadvantage of poor film property control because of a lack of substrate motion.

Another class of conventional PVD modules or tools relies on planetary motion of the substrate when depositing a film stack. Rather than depositing the films with the substrate stationary, these tools spin the substrate as it is scanned past the sputter source to achieve the specified film parameters. These tools generally are about the same size as the dial-index tools. The substrate fixture, which is also at the end of a rotary arm, incorporates provisions to continuously rotate the substrate at relatively high speed during a deposition cycle. The radius of rotation is such that the center of the substrate is approximately aligned with the center of the sputter source.

The basic layout of these planetary PVD tools is similar to that of the dial-index tools. The sputter sources are similarly located on the top of a round vacuum chamber at about the same source-to-substrate distance but are usually rectangular rather than round. The length of the sputter sources is usually 1.5 to 2.0 times the substrate diameter to assure good intrinsic thickness uniformity for the film deposited on the substrate. However, the required characteristics of the deposited film (e.g., uniformity and thickness control) are achieved by the control of the scanning motion of the spinning substrate under the sputter source. A shutter is not used to control the deposition process, in contrast to dial-index designs.

Compared with the dial-index design, planetary motion generally achieves superior film thickness and uniformity tolerances due primarily to the scanning motion. However, the size and cost are on the same order for both the dial-index and planetary tool designs. Both of these classes of PVD modules and tools require large and expensive chambers because of the individual deposition zones required for each material and present significant footprint needs and cost-of-ownership to the user.

What is needed, therefore, is a compact and economical PVD tool or module capable of depositing thin film multi-layers with tight control over film thickness, film uniformity, and film surface smoothness.

### SUMMARY OF THE INVENTION

In accordance with an embodiment of the invention, a deposition system for forming at least one layer on a substrate comprises a vacuum chamber and a plurality of deposition sources arranged inside the vacuum chamber. Each of the deposition sources is capable of emitting a flux of deposition material impinging a common deposition area defined in a substrate plane inside the vacuum chamber. A substrate carrier holds the substrate inside the vacuum chamber at a position confronting the deposition sources. The substrate carrier may include a first drive for spinning the substrate and a second drive for moving the substrate in the substrate plane through the common deposition area so that the flux of deposition material deposits on the substrate to form the layer. The system further includes a deposition plate positioned between the deposition sources and the substrate stage. The deposition plate features a deposition aperture defining the common deposition area.

In accordance with an embodiment of the invention, a method of depositing at least one layer on a substrate comprises aiming a first deposition source and a second deposition source confocally so that a first deposition flux emitted from the first deposition source and a second flux emitted from the second deposition source impinges a common deposition area. The method further includes operating the first deposition source to emit the first deposition flux, spinning a substrate about a surface normal, and moving the spinning substrate through the common deposition area so that the first deposition flux accumulates on the substrate as a first layer.

The present invention creates a compact and economical PVD module that is capable of depositing thin film multi-layers with extreme control of thickness, uniformity and surface smoothness. The present invention creates a compact module capable of generating extremely well controlled multi-layer films by arranging multiple cathodes in a conical cluster about a single deposition zone while using two independently controlled (rotation and scanning) substrate motions to achieve the required film thickness, uniformity and surface smoothness parameters. The present invention does not require or utilize a shutter to control the film deposition.

The present invention relates to a compact multi-sputter source deposition chamber, with a confocal arrangement of the sputter sources and a deposition aperture to precisely define the deposition zone. The chamber is provided with a substrate carrier that rotates the substrate at high speed. The substrate carrier is translated through the deposition zone created by the deposition aperture plate by, for example, a servomotor drive. Managed control of the motion and deposition flux while the substrate is passed through the deposition zone is used to achieve precise control of film thickness, uniformity and smoothness.

The module or tool of the present invention overcomes the performance limitations of static deposition and tilted cathode deposition modules and, furthermore, overcomes the size and cost disadvantage of static and planetary deposition modules. The module or tool of the present invention can achieve the deposited film tolerances characteristic of a planetary motion module in a footprint of similar size to that of a tilted cathode module.

These and other objects and advantages of the present invention shall become more apparent from the accompanying drawings and description thereof.

### BRIEF DESCRIPTION OF THE DRAWINGS

The accompanying drawings, which are incorporated in and constitute a part of this specification, illustrate embodiments of the invention and, together with a general description of the invention given above, and the detailed description of the embodiments given below, serve to explain the principles of the invention.

FIG. 1 is a partial cross-sectional view of a processing apparatus in accordance with the present invention;

FIG. 2 is top view inside the vacuum chamber of the apparatus of FIG. 1 viewed from a perspective along the vertical centerline of the vacuum chamber;

FIG. 3 is a top view of a processing apparatus in accordance with an alternative embodiment of the present invention; and

FIG. 4 is a diagrammatic perspective view of a processing apparatus in accordance with another alternative embodiment of the present invention.

### DETAILED DESCRIPTION OF SPECIFIC EMBODIMENTS

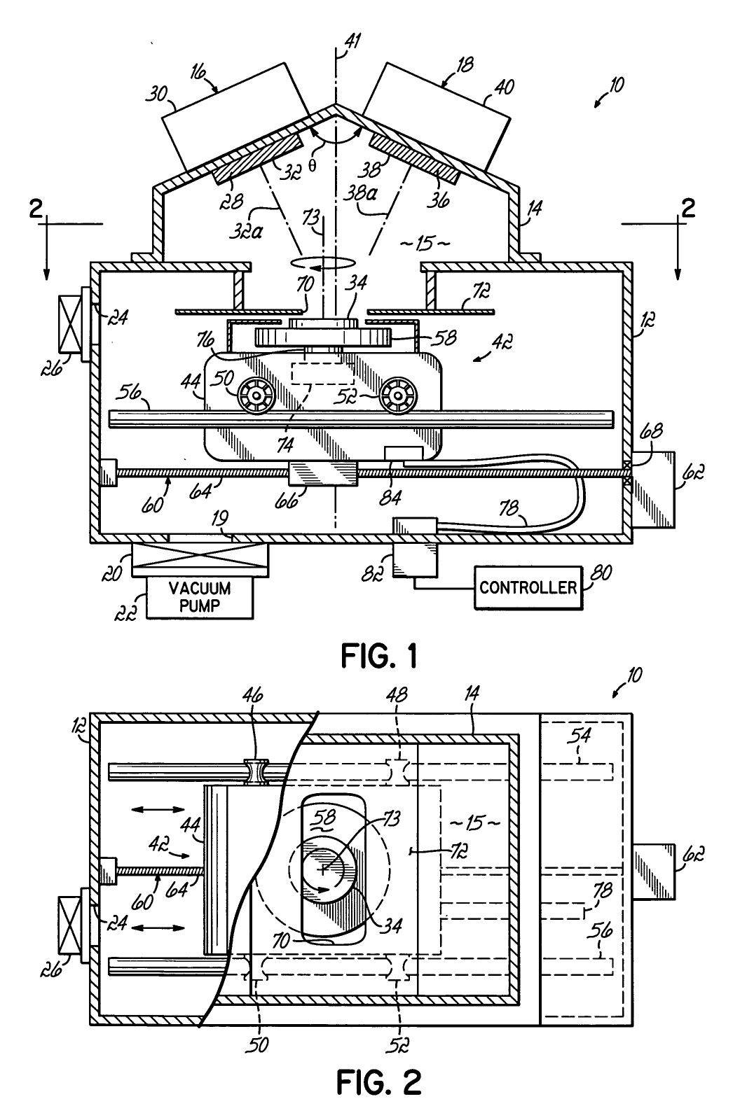

With reference to FIG. 1, a processing apparatus 10 in accordance with the invention includes a vacuum chamber 12 and a chamber lid 14 defining an evacuable or controlled atmosphere volume 15. A set or cluster of deposition sources 16, 18 is mounted on the chamber lid 14. Typically, the apparatus 10 will include between two and six individual deposition sources, although only two deposition sources 16, 18 are shown in FIG. 1. An exhaust port 19 of the vacuum chamber 12, which is isolated from the surrounding environment, is, selectively coupled by a gate valve 20 with a vacuum pump 22 for evacuating the controlled atmosphere volume 15. The vacuum chamber 12 is also supplied with process gases as understood by persons of ordinary skill in the art. The controlled atmosphere volume 15 of vacuum chamber 12 is accessed through a substrate load port 24. The load port 24 is normally isolated from the vacuum chamber 12 by a suitable isolation valve 26. The isolation valve 26 may be a Modular Equipment Subcommittee for Communications (MESC) style slit or gate valve. The load port 24 may also be compliant with the MESC standard load/unload provisions of a cluster tool module so as to be compatible with commercial cluster tool hubs and transfer robots.

Deposition source 16 may be any vacuum-compatible device recognized by persons of ordinary skill in the art as having the capability of creating a flux of deposition material. Deposition source 16 is illustrated as a magnetron cathode that includes a sputtering target 28 located inside the vacuum chamber 12 and a magnetron 30 positioned behind the sputtering target 28 that provides a magnetic field at a front target surface 32 of the sputtering target 28. The sputtering target 28 is connected to an electrical power supply (not shown) which, when energized, generates an electric field inside the vacuum chamber 12. The vacuum chamber 12 is evacuated by the vacuum pump 22 and then filled at a low pressure with a suitable inert gas, such as argon. The electric field generates a plasma discharge in the inert gas adjacent to the sputtering target 28. The magnetron 30 supplies a magnetic field that confines and shapes the resulting plasma near the front target surface 32. Positively-charged ions from the plasma are accelerated toward the negatively-biased sputtering target 28, where the ions bombard the front target surface 32 with sufficient energy to sputter atoms of the target material. The flux of sputtered target material travels ballistically toward a substrate 34 positioned in opposition to the sputtering target 28 inside the vacuum chamber 12. Deposition source 18 is likewise illustrated as a magnetron cathode consisting of a sputtering target 36 having a front target surface 38 and a magnetron 40.

The deposition sources 16, 18 are arranged symmetrically about a confocal axis 41, which typically coincides with a vertical centerline of the chamber lid 14. The deposition sources 16, 18 may be activated simultaneously or separately, depending on the application and the desired characteristics of the film or film stack being deposited on a substrate 34. For forming a film stack or multi-layer film with layers of several different materials, it is contemplated that the target material of sputtering target 28 may differ from the target material of sputtering target 36. By selecting from among the available deposition sources 16, 18, one or more materials can then be deposited or co-deposited on the substrate 34 to form an individual layer in the multi-layer film. The deposition sources 16, 18 may be sequentially operated to deposit a desired sequence of layers on substrate 34. The chamber lid 14 includes provisions, like baffles and shields, suitable to prevent cross-contamination of the sputtering targets 28, 36.

The deposition sources 16, 18, which are mounted to the conical inclined wall of the chamber lid 14, are oriented with a confocal alignment such that the sputtered target atoms from each of the sputtering targets 28, 36 cover an overlapping deposition zone or area defined in the plane of the substrate 34. The confocal orientation is provided by adjusting the included angle, 0, of the chamber lid 14 so that the sputtering targets 28, 36 are tilted or inclined relative to the plane of the substrate 34 and the plane of a deposition aperture 70. The included angle defined by the inclined wall of the chamber lid 14 will depend upon the chamber dimensions. This inclination of the sputtering targets 28, 36 provides the confocal alignment with the deposition zone.

A plume of sputtered deposition material emitted from deposition source 16 generally has a flux distribution that is centered about a normal surface axis 32a of target surface 32. Similarly, a plume of sputtered deposition material emitted from deposition source 18 generally has a flux distribution that is centered about a normal surface axis 38a of target surface 38. Other deposition sources (not shown) of the processing apparatus 10 have a similar surface axis defined for their respective flux distributions. Generally, the surface axes 32a, 38a are aimed at the geometrical center of the deposition aperture 70. The invention contemplates that, as the target surfaces 32, 38 are eroded by sputtering, the aiming of the surface axes 32a, 38a may change slightly. However, the surface axes 32a, 36a will remain aimed generally at the geometrical center of the deposition aperture 70.

With reference to FIGS. 1 and 2, a substrate carrier assembly 42 is mounted to the vacuum chamber 12 and includes a carrier 44 supported by a plurality of rollers 46, 48, 50, 52 upon a pair of support rails 54, 56 mounted to the vacuum chamber 12. The substrate 34 is held by a rotary substrate nest 58 carried by the carrier 44. A linear drive 60 moves and positions the carrier 44 within the vacuum chamber 12. The linear drive 60 includes a bi-directional drive or motor 62, such as a servomotor, that is adapted to control the rotation of a threaded lead screw 64. The underside of the carrier 44 includes a threaded thrust nut 66 engaged with the threads on the lead screw 64. When the motor 62 is energized to rotate the lead screw 64, the thrust nut 66 travels along the lead screw 64, thereby urging the carrier 44 into motion within the vacuum chamber guided by the engagement between the rollers 46, 48, 50, 52 and support rails 54, 56. A vacuum feedthrough 68 is provided in the vacuum chamber 12 for transferring the motive force from the motor 62 to the lead screw 64. In alternative embodiments, the linear drive 60 may comprise any motion-producing device suitable for positioning substrate carrier assembly 42. Such actuators include pneumatic cylinders, hydraulic cylinders, ball screws, stepper motors, and solenoids, among other known devices suitable for linear actuation.

Rectilinear motion of the carrier assembly 42 driven by the linear drive 60 is used to position the carrier 44 proximate to the load port 24 for exchange of coated and uncoated substrates 34. The carrier 44 includes actuators and sensors suitable for the loading and clamping of the substrate 34 to the rotary substrate nest 58. The linear drive 60 is also used to move the motion of the carrier 44 past a deposition aperture 70 defined in a deposition aperture plate 72 positioned between the deposition sources 16, 18 and the substrate 34.

The support rails 54, 56, rollers 46, 48, 50, 52, and lead screw 64 are preferably fabricated from vacuum compatible materials that require little or no lubrication and generate few wear particles. If lubricants are required, only those lubricants compatible with high vacuum environments are specified.

A rotary drive 74 positioned inside the substrate carrier 44 rotates or spins the substrate nest 58 about a vertical axis 73. The interior space of the substrate carrier 44 is at atmospheric pressure and sealed from the vacuum environment of the vacuum chamber 12. The rotary drive 74 is any mechanism that is capable of rotating a shaft 76, such as a stepper motor, a servomotor, a rotary hydrostatic actuator, a hydraulic actuator, or the like. Shaft 76 couples the substrate nest 58 and rotary drive 74 through a rotary vacuum seal, as the interior volume of the substrate carrier 44 is at atmospheric pressure. Sensors (not shown) are provided on the substrate carrier 44 for aligning the substrate nest 58 to load and unload substrates 34 at the load port 24.

A control system (not shown) orchestrates the operation of the deposition sources 16, 18, the linear drive 60, and rotary drive 74 during a deposition process. More specifically, the speed of the rectilinear motion of substrate carrier 44, the angular velocity of the substrate nest 58, and the fluxes from the deposition sources 16, 18 are controlled by the control system, which has a construction understood by persons of ordinary skill in the art. One or both of the fluxes from deposition sources 16, 18 may be discontinued by reducing the operating power.

A vacuum-compatible umbilical 78 includes shielded electrical conductors to transfer power and control signals inside the vacuum chamber 12 from an external controller 80 to the substrate carrier assembly 42. The umbilical 78 has a length and flexibility that accommodate movement of the carrier 44 by linear drive 60 over its full range of motion. The umbilical 78 is coupled on one end with an electrical feedthrough 82 extending through the vacuum chamber 12 and that communicates externally with the controller 80. The opposite end of the umbilical 78 is coupled by another electrical feedthrough 84 with rotary drive 74. The atmosphere-to-vacuum electrical feedthroughs 82, 84 serve both a vacuum seal function and an electrical insulating function. Additionally, the substrate carrier assembly 42 may be provided with substrate RF bias and magnetic alignment, if specified by the application.

The deposition aperture plate 72 is mounted in the vacuum chamber 12 at a height adequate to allow the substrate carrier assembly 42 to pass during its scanning motion with minimal clearance to precisely control the deposition zone. The deposition aperture plate 72 is located such that the deposition aperture 70 is symmetrical with respect to the confocal axis 41 about which the sputtering targets 28, 36 are arranged. To achieve the required film thickness, uniformity and smoothness parameters requires the management of the deposition by simultaneous control of the scanning motion of the substrate 34 under the deposition aperture 70 and control of the sputtered material flux with respect to the location of the substrate 34 in the deposition zone. The substrate 34 is rotated at high speed relative to the translation velocity while passing through the deposition zone.

The dimensions of the deposition aperture 70 determine the effective area of the deposition zone in the plane of the substrate 34. The deposition zone is defined by the projection of the flux of sputtered deposition material from the deposition sources 16, 18 through the deposition aperture 70. Deposition material having trajectory angles outside of the area of the deposition aperture 70 collide with the deposition plate 72. Only deposition material having angles of incidence relative to the plane of the deposition plate 72 within the boundary of the deposition aperture 70 are not intercepted by deposition plate 72 and are deposited upon the confronting surface of substrate 34.

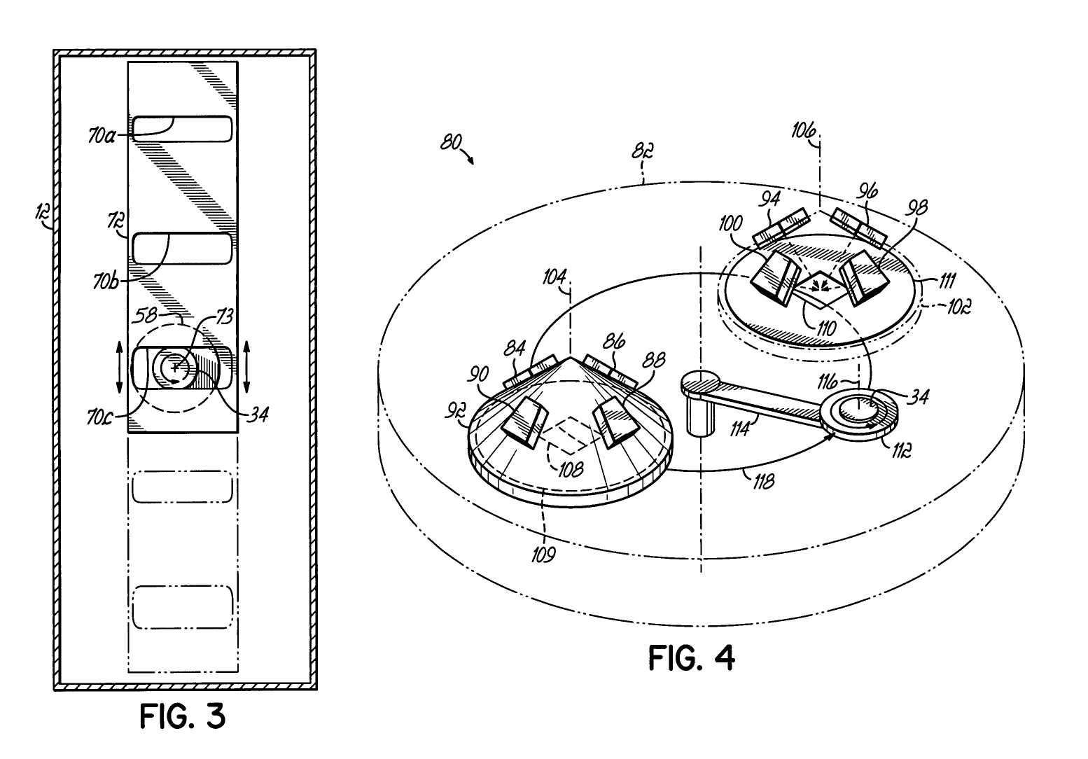

With reference to FIG. 3 in which like reference numerals refer to like features in FIGS. 1 and 2 and in an alterative embodiment of the invention, the deposition aperture plate 72 may include multiple deposition apertures 70a, 70b, 70c for collimating the flux of deposition material arriving from the deposition sources 16, 18. One of the deposition apertures 70a, 70b, 70c is indexed into alignment with the confocal axis 41 of the deposition sources 16, 18. Deposition apertures 70a, 70b, 70c have individual aperture shapes optimized for the deposition of individual materials and/or groups of materials.

In use, the carrier 44 is positioned proximate to the load port 24 by operation of the linear drive 60, the isolation valve 26 is actuated to an opened condition, a substrate 34 is transferred to the substrate nest 58, and the isolation valve 26 is closed. The carrier 44 is repositioned by the linear drive 60 to a location proximate the deposition aperture 70. The environment inside the controlled atmosphere volume 15 is adjusted to provide a sub-atmospheric atmosphere suitable for operation of the deposition sources 16, 18. One or both of the deposition sources 16, 18 is energized to provide a flux of deposition material directed toward the deposition zone at the plane of the substrate 34 defined by deposition aperture 70. The deposition sources 16, 18 are oriented with a confocal alignment such that the sputtered target atoms from each of the sputtering targets 28, 36 cover an overlapping deposition area defined in the plane of the substrate 34 by the shared deposition aperture 70.

The linear drive 60 is operated to move the carrier 44 and substrate 34 supported by the substrate nest 58 on the carrier 44 repeatedly through the deposition zone at a given linear velocity, while the rotary drive 74 is operated to spin the substrate 34 at a given angular velocity. The carrier 44 is repeatedly moved through the deposition zone with a number of passes calculated to provide the desired film thickness. The deposition sources 16, 18 may be operated sequentially for depositing a layer stack with individual layers formed from disparate deposition materials. After the deposition process is completed, the carrier 44 is again positioned by the linear drive 60 proximate to the load port 24, the isolation valve 26 is actuated to an opened condition, the coated substrate 34 is transferred out of the vacuum chamber 12, another uncoated substrate 34 is positioned on the substrate nest 58, and the isolation valve 26 is closed so that another deposition may be performed.

With reference to FIG. 4 in which like reference numerals refer to like features in FIGS. 1 and 2, a processing apparatus 80 includes a vacuum chamber 82 similar to vacuum chamber 12, a set or cluster of confocal deposition sources 84, 86, 88, 90 provided in a chamber lid 92, and a separate set or cluster of confocal deposition sources 94, 96, 98, 100 provided in a chamber lid 102. Each of the chamber lids 92, 102 has a vacuum-sealed engagement with the vacuum chamber 82.

Each of the deposition sources 84, 86, 88, 90 and deposition sources 94, 96, 98, 100 is configured with a magnetron and sputtering target, as described above with regard to deposition sources 16, 18. The deposition sources 84, 86, 88, 90 are oriented relative to a confocal axis 104 by selection of a suitable included angle for chamber lid 92. Similarly, deposition sources 94, 96, 98, 100 are oriented relative to a confocal axis 106 by selection of a suitable included angle for chamber lid 102. The deposition flux emitted by each of the deposition sources is generally centered about a surface normal axis.

Deposition sources 84, 86, 88, 90 are confocally aligned with an aperture 108 in a deposition aperture plate 109 and deposition sources 94, 96, 98, 100 are confocally aligned with an aperture 110 in a deposition aperture plate 111. Generally, the surface normal axis of each of the deposition sources is aligned with the geometrical center of the corresponding aperture 108, 110. Each of the apertures 108, 110 defines a deposition area or zone in the plane of the substrate 34 across which the substrate 34 may be exposed to the deposition flux arriving from the respective deposition source clusters. Each of the two respective deposition apertures 108, 110 may be individually optimized for depositing different classes of materials with dissimilar angular distributions of sputtered material among the two deposition source clusters.

The substrate 34 is supported on a substrate nest 112, similar to substrate nest 58, at the end of an arm 114. Substrate nest 112 is configured with a rotary drive (not shown) that rotates or spins substrate 34 about a vertical axis 116. Arm 114 is coupled with a robot equipped to rotate the substrate nest 112 and substrate 34 in a planetary motion, as diagrammatically indicated by reference numeral 118. The radius of the planetary motion 118 is chosen such that the substrate 34 passes through the deposition zones defined by apertures 108 and 110 once per planetary revolution. While positioned in the deposition zones, the confronting surface of substrate 34 is exposed to deposition fluxes that accumulate as a thin film. The composition of the thin film or different layers in a layer stack is determined by the specific deposition sources 84, 86, 88, 90 and deposition sources 94, 96, 98, 100 that are operating during the planetary motion 118 of substrate 34. Although only one arm 114 is shown, a person of ordinary skill in the art will appreciate that multiple arms similar to arm 114 may be arranged in a hub and spoke arrangement for use in moving multiple substrates 34 through the deposition zones defined by apertures 108 and 110. Exemplary planetary motion systems are described in U.S. Pat. No. 5,795,448, which is hereby incorporated by reference herein in its entirety.

The arrangement of the deposition source clusters improves on conventional deposition source arrangements in which sputter sources are arranged radially in a lid of the vacuum chamber and parallel to the substrate. Specifically, the use of an aperture and confocally arranged sputter sources in accordance with the invention permits reductions in the size of the vacuum chamber as compared with these conventional arrangements.

The use of planetary substrate motion results in a less compact module than the linear scan implementation described with regard to FIGS. 1 and 2. The number of depositions sources located confocally about any single deposition aperture may be reduced. However, the total number of deposition sources in a given processing apparatus may be increased without a significant increase in the length and cost of the apparatus as would be true for rectilinear scanning. By reducing the number of deposition sources at a given deposition aperture in the planetary design, the angle of each individual deposition source with respect to the substrate normal may be reduced. The resulting more normal angle for the arriving deposition flux with respect to the substrate may be desirable for symmetrically coating three-dimensional features projecting from the substrate.

While the present invention has been illustrated by a description of various embodiments and while these embodiments have been described in considerable detail, it is not the intention of the applicant to restrict or in any way limit the scope of the appended claims to such detail. Additional advantages and modifications will readily appear to those skilled in the art. Thus, the invention in its broader aspects is therefore not limited to the specific details, representative apparatus and method, and illustrative example shown and described. Accordingly, departures may be made from such details without departing from the spirit or scope of applicant's general inventive concept.

What is claimed is:

1. A deposition system for forming at least one layer on a substrate, comprising:
a vacuum chamber;
a plurality of deposition sources inside said vacuum chamber, each of said deposition sources capable of emitting a flux of deposition material impinging a common deposition area defined in a substrate plane inside said vacuum chamber;
a substrate carrier for holding the substrate inside said vacuum chamber at a position confronting said deposition sources, said substrate carrier including a first drive for moving the substrate in said substrate plane through said common deposition area so that the flux of deposition material deposits on the substrate to form the layer; and
a deposition plate positioned between said deposition sources and said substrate carrier, said deposition plate including a deposition aperture defining said common deposition area in the substrate plane.

2. The deposition system of claim 1 wherein said vacuum chamber includes a chamber lid having a conical wall converging at a central axis, and each of said deposition sources is mounted to said conical wall about said central axis and oriented to emit the corresponding flux of deposition material toward said common deposition area.

3. The deposition system of claim 2 wherein said deposition aperture has a geometrical center and said central axis intersects said deposition aperture near said geometrical center.

4. The deposition system of claim 1 wherein each of said deposition sources includes a sputtering target adapted to emit the corresponding flux of deposition material when exposed to a plasma and a magnetron for confining the plasma adjacent to said sputtering target.

5. The deposition system of claim 1 wherein said first drive of said substrate carrier is configured to translate in a rectilinear path through said deposition area.

6. The deposition system of claim 1 wherein said first drive of said substrate carrier is configured to translate in a planetary path through said common deposition area.

7. The deposition system of claim 1 wherein said substrate carrier further comprises a second drive for spinning the substrate as the substrate is moved in said substrate plane through said common deposition area.

8. The deposition system of claim 1 wherein said deposition plate includes a plurality of apertures, said deposition plate being movable relative to said deposition sources for positioning different ones of said apertures to define a corresponding plurality of geometrical shapes for said common deposition area.

9. A deposition system for forming at least one layer on a substrate, comprising:
a vacuum chamber;
a first plurality of deposition sources arranged inside said vacuum chamber, each of said first plurality of deposition sources capable of emitting a flux of deposition material impinging a first common deposition area defined in a substrate plane inside said vacuum chamber;
a second plurality of deposition sources arranged inside said vacuum chamber, each of said second plurality of deposition sources capable of emitting a flux of deposition material impinging a second common deposition area defined in the substrate plane;
a substrate carrier for holding the substrate inside said vacuum chamber at a position alternatively confronting said first plurality of deposition sources or said second plurality of deposition sources, said substrate carrier including a first drive for moving the substrate in said substrate plane through said first common deposition area and said second common deposition area;
a first deposition plate positioned between said first plurality of deposition sources and said substrate carrier, said first deposition plate including a first deposition aperture defining said first common deposition area in the substrate plane; and
a second deposition plate positioned between said second plurality of deposition sources and said substrate carrier, said second deposition plate including a second deposition aperture defining said second common deposition area in the substrate plane.

10. The deposition system of claim 9 wherein said vacuum chamber includes a first chamber lid having a conical wall converging at a central axis, and each of said first plurality of deposition sources is mounted to said conical wall of said first chamber lid about said central axis and oriented to emit the corresponding flux of deposition material toward said first common deposition area.

11. The deposition system of claim 10 wherein said vacuum chamber includes a second chamber lid having a conical wall converging at a central axis, and each of said second plurality of deposition sources is mounted to said conical wall of said second chamber lid about said central axis and oriented to emit the corresponding flux of deposition material toward said second common deposition area.

12. The deposition system of claim 9 wherein each of said first plurality of deposition sources includes a sputtering target adapted to emit the corresponding flux of deposition material when exposed to a plasma and a magnetron for confining the plasma adjacent to said sputtering target.

13. The deposition system of claim 12 wherein each of said second plurality of deposition sources includes a sputtering target adapted to emit the corresponding flux of deposition material when exposed to a plasma and a magnetron for confining the plasma adjacent to said sputtering target.

14. The deposition system of claim 9 wherein said first drive of said substrate carrier is configured to translate in a rectilinear path through said common deposition area.

15. The deposition system of claim 9 wherein said first drive of said substrate carrier is configured to translate in a planetary path through said common deposition area.

16. The deposition system of claim 9 wherein said substrate carrier further comprises a second drive for spinning the substrate as the substrate is moved in said substrate plane through said common deposition area.

17. A method of depositing at least one layer on a substrate, comprising:
aiming a first deposition source and a second deposition source confocally so that a first deposition flux emitted from the first deposition source and a second flux emitted from the second deposition source impinges a common deposition area;
operating the first deposition source to emit the first deposition flux; and
moving the substrate through the common deposition area so that the first deposition flux accumulates on the substrate as a first layer.

18. The method of claim 17 further comprising:
causing the first deposition source to cease emitting the first deposition flux;
operating the second deposition source to emit the second deposition flux; and
moving the spinning substrate through the common deposition area so that the second deposition flux accumulates on the substrate as a second layer.

19. The method of claim 18 further comprising:
positioning a first aperture characterized by a first geometrical shape between the first and second deposition sources and the common deposition area when the first deposition source is operating; and
positioning a second aperture characterized by a second geometrical shape between the first and second deposition sources and the common deposition area when the second deposition source is operating.

20. The method of claim 17 further comprising:
operating the second deposition source to emit the second deposition flux; and
moving the spinning substrate through the common deposition area so that the first and second deposition fluxes co-deposit in the first layer on the substrate.

21. The method of claim 17 wherein moving the spinning substrate further comprises:
translating the substrate in a rectilinear path through the common deposition area.

22. The method of claim 17 wherein moving the spinning substrate further comprises:
translating the substrate in a planetary path through the common deposition area.

23. The method of claim 17 further comprising:
positioning a first aperture between the first and second deposition sources and the common deposition area to define the common deposition area.

24. The method of claim 17 further comprising:
spinning a substrate about a surface normal as the substrate is moved through the common deposition area.
